(19) United States
(12) Patent Application Publication
(10) Pub. No.: US 2024/0186210 A1
(43) Pub. Date: Jun. 6, 2024

(54) ELECTRICAL AND/OR ELECTRONIC DEVICE

(71) Applicant: Robert Bosch GmbH, Stuttgart (DE)

(72) Inventors: Daniel Stehlik, Moessingen (DE); Valentin Ruedenauer, Reutlingen (DE)

(21) Appl. No.: 18/526,098

(22) Filed: Dec. 1, 2023

(30) Foreign Application Priority Data
Dec. 6, 2022 (DE) 10 2022 213 162.2

(51) Int. Cl. H01L 23/367; H01L 23/373

(52) U.S. Cl. CPC H01L 23/367; H01L 23/3736

(57) ABSTRACT

For an electrical and/or electronic device, comprising at least one cooling device having a top side, an electrical and/or electronic assembly arranged on the top side of the cooling device having a contact surface, wherein the contact surface faces the top side of the cooling device and is attached to the top side of the cooling device by means of an intermediate layer arranged between the cooling device and the contact surface of the electrical and/or electronic assembly, it is proposed that a coating extending flat is arranged on the top side of the cooling device, wherein the coating on the top side of the cooling device comprises at least one recess, in which the top side of the cooling device is not coated, wherein the contact surface of the electrical and/or electronic assembly in the recess is in contact with the cooling device and attached to the cooling device.

### BACKGROUND OF THE INVENTION

The invention relates to an electrical and/or electronic device. Furthermore, the invention relates to a method for manufacturing an electrical and/or electronic device.

In hybrid vehicles or electric vehicles, electrical and/or electronic assemblies, for example power modules, such as inverter structures or converter structures, are employed. For example, to operate an electric machine, inverters that provide phase currents to the electric machine are used. The power modules may comprise a carrier substrate having traces on which, for example, power semiconductors are arranged that together with the carrier substrate form an electronic unit. In operation, heat is generated by the electrical unit, which must be dissipated to a cooling device. For this purpose, the electronic unit is thermally connected to the cooling device. Power substrates are applied to the cooling device. The cooling device may be formed from aluminum, AlSiC alloys, or copper alloys. For the purpose of a low thermal resistance between power substrate and cooling device, the power substrate is joined to the cooling device by means of a soft soldering process, optionally also a sintering or lamination process.

### SUMMARY OF THE INVENTION

According to the invention, an electrical and/or electronic device is proposed. The electrical and/or electronic device comprises at least one cooling device having a top side, an electrical and/or electronic assembly arranged on the top side of the cooling device having a contact surface, wherein the contact surface faces the top side of the cooling device and is attached to the top side of the cooling device by means of an intermediate layer arranged between the cooling device and the contact surface of the electrical and/or electronic assembly. According to the invention, a coating extending flat on the top side of the cooling device is arranged on the top side of the cooling device, wherein the coating on the top side of the cooling device comprises at least one recess in which the top side of the cooling device is not coated, wherein the contact surface of the electrical and/or electronic assembly in the recess is in contact with the cooling device and is attached to the cooling device.

The recess in the coating may advantageously provide the position for the intermediate layer and for the contact surface of the electrical and/or electronic assembly on the cooling device. Thus, the electrical and/or electronic assembly may be advantageously simply and accurately positioned on the top side of the cooling device. For example, the coating may protect the cooling device from corrosion, whereas the material of the cooling device underlying the coating is exposed in the recess of the coating and used to connect the electrical and/or electronic assembly to the cooling device. For example, a copper surface of the cooling device on which the electrical and/or electronic assembly may be soldered by means of a soft solder may be exposed in the recess.

Further advantageous configurations and further developments of the invention are made possible by the features specified in the subclaims.

According to an advantageous embodiment, it is provided that the contact surface of the electrical and/or electronic assembly is soldered in the recess of the coating to the top side of the cooling device, wherein the intermediate layer is configured as a solder layer. In addition to the positioning aid, a solder stop function is further provided by the recess in the coating. The coating prevents the soldering layer on the top side of the cooling device from spreading in a plane parallel to the top side of the cooling device beyond the recess in the coating. As the electrical and/or electronic assembly is soldered onto the cooling device, the soldering layer cannot spread beyond the recess. Thus, the recess provides a fixed position for the intermediate layer by means of which the electrical and/or electronic assembly is attached to the cooling device.

According to an advantageous exemplary embodiment, it is provided that the cooling device is formed from copper, in particular as a copper plate. The use of a copper plate provides as little thermal resistance as possible. At the same time, the electrical and/or electronic assembly may be soldered onto the copper plate and thus attached. On the side facing away from the top side of the cooling device, a cooling structure, for example a pinfin structure, can be configured on the cooling device. Furthermore, a cooling structure, for example a rib structure, can be soldered on the side facing away from the top side of the cooling device. Such a cooling structure serves to increase the surface area and can simultaneously act as a turbulence structure to deliver more heat to the cooling medium. For example, the cooling structure may be adjacent to a cooling channel. The cooling channel can be produced via a brazing process or via additional forming components, which are pressed and sealed together with the copper plate.

According to an advantageous embodiment, it is provided that the coating is formed from nickel. The coating with nickel protects the cooling device from corrosion at the coated locations. The coating with nickel may be chemical, for example, and may also extend across further surfaces of the cooling device, for example. Furthermore, the melting and blurring of the solder used to attach the electrical and/or electronic assembly, which is in particular a soft solder, is limited by the coating of nickel, as this has a poorer wetting behavior than the copper surface exposed in the recess of the coating.

According to an advantageous exemplary embodiment, it is provided that the recess has a larger surface extent than the contact surface. Thus, the electrical and/or electronic assembly may be advantageously well and easily placed in the recess of the coating.

According to an advantageous embodiment, it is provided that the contact surface is arranged on the top side of the cooling device entirely within the recess of the coating. The entire contact surface can thus be attached to the cooling device by means of the intermediate layer, which is in particular configured as a soldering layer.

According to an advantageous embodiment, it is provided that the intermediate layer is arranged on the top side of the cooling device entirely within the recess of the coating. The coating limits the spread of the intermediate layer, which is formed as a solder layer, to the surface of the recess.

Furthermore, a method for manufacturing an electrical and/or electronic assembly is proposed. The method comprises a step of providing a cooling device with a top side, a step of coating the top side of the cooling device with a coating, wherein the coating is carried out by leaving out a recess on the top side of the cooling device, wherein the top side of the cooling device is not coated in the recess. The method further comprises a step of providing an electrical and/or electronic assembly having a contact surface and a step of arranging and attaching the contact surface of the electrical and/or electronic assembly in the recess on the top side of the cooling device by means of an intermediate layer, in particular configured as a solder layer. Thus, the coating on the recess does not have to be subsequently mechanically removed to allow the electrical and/or electronic assembly to be attached by means of the intermediate layer, but the coating is only applied to the desired locations from the outset. The electrical and/or electronic assembly may be soldered to the top side of the cooling device in the recess. The coating surrounding the recess then serves to position the electrical and/or electronic assembly and also has a solder stop function, and limits the possibility of spreading of the solder layer on the top side of the cooling device.

According to an advantageous embodiment, it is provided that the top side of the cooling device is masked prior to coating. Thus, the top side may be provided with the coating at the desired locations while leaving the recess in the coating free.

According to an advantageous embodiment, it is provided that masking of the top side of the cooling device is carried out by clamping on a full-surface mask and/or by clamping on an edge-limiting mask and/or by masking off.

### BRIEF DESCRIPTION OF THE DRAWINGS

An exemplary embodiment of the invention is shown in the drawing and explained in further detail in the following description. Shown are:

FIG. 1 an exemplary embodiment of the cooling device,

FIG. 2 an exemplary embodiment of an electrical and/or electronic device comprising the cooling device of FIG. 1,

FIG. 3 a cross-section through the exemplary embodiment of the electrical and/or electronic device of FIG. 2,

FIG. 4 a plan view of the exemplary embodiment of the electrical and/or electronic device of FIG. 2 with an enlarged section.

### DETAILED DESCRIPTION

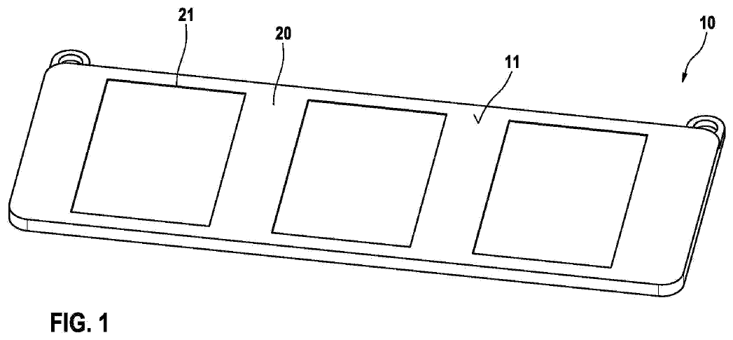

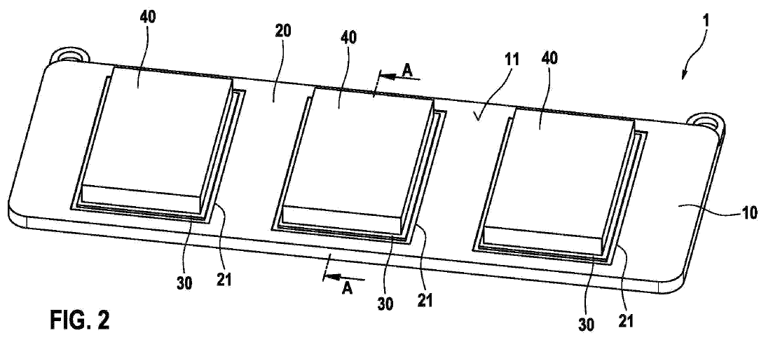

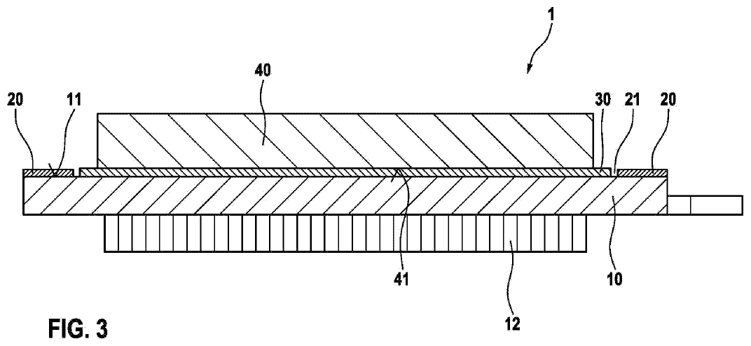

FIG. 1 shows an exemplary embodiment of a cooling device 10 of an electrical and/or electronic device 1. FIGS. 2-4 show an exemplary embodiment of the electrical and/or electronic device 1.

The electrical and/or electronic device 1 comprises the cooling device 10. A flat top side 11 is configured on the cooling device 10. An electrical and/or electronic assembly 40 is arranged on the top side 11 of the cooling device 10. The heat sink 10 is made of copper. The cooling device 10 is configured as a plate in the illustrated exemplary embodiment. For example, the plate is a copper plate and is formed entirely from copper. Copper also includes copper alloys. On the side of the cooling device 10 facing away from the top side 11 of the cooling device 10, a cooling structure 12 is configured, for example, to improve the heat dissipation. For example, ribs, pins, cylindrical, oval, or other shaped pins or channels may be configured as structures for improving heat dissipation. In this exemplary embodiment, pins are configured on the cooling device 10 as structures to improve heat dissipation on the side facing away from the top side 11 of the cooling device 10. In this regard, a cooling medium may flow around the surface-enlarging cooling structure 12 through a cooling channel of the heat sink, for example, when the plate is assembled with other cooling elements to form a heat sink. The top side 11 of the cooling device 10 in this exemplary embodiment is a flat surface. The electrical and/or electronic assembly 40 is soldered to the top side 11 of the cooling device 10.

The cooling device 1 is used to cool one or more electrical and/or electronic assemblies 40, for example power circuits. These may be, for example, power circuits, such as inverter structures or converter structures, of hybrid vehicles or electric vehicles. For example, the electrical and/or electronic assembly 40 may be configured as a power module and comprise, for example, a carrier substrate having traces on which, for example, power semiconductors are arranged to form an electronic unit together with the carrier substrate. The electrical and/or electronic assembly 40 has a contact surface 41. For example, the contact surface 41 is flat. For example, the contact surface 41 may be configured on a bottom side of a carrier substrate of the electrical and/or electronic assembly 40. For example, the contact surface 41 may be made of copper.

In operation, heat is generated by the electrical and/or electronic assembly 40, which must be dissipated to a cooling device 1. For this purpose, the electrical and/or electronic assembly 40 is arranged on the top side 11 of the cooling device 1. An intermediate layer 30 for the attachment and thermal connection of the electrical and/or electronic assembly 40 on the cooling device 1 is arranged between the cooling device 1 and the electrical and/or electronic assembly 40. The intermediate layer 30 is configured as a solder layer, in particular from a soft solder. The intermediate layer 30 is melted on the contact surface 41 of the electrical and/or electronic assembly 40 and on the top side 11 of the cooling device 10. The intermediate layer 30 adheres to the contact surface 41 of the electrical and/or electronic assembly 40 and to the top side 11 of the cooling device 10 in a material-locking manner. The electrical and/or electronic assembly 40 is soldered to the top surface 11 of the cooling device 10 by means of a soft soldering process. The intermediate layer 30 separates the top side 11 of the cooling device 10 and the contact surface 41 of the electrical and/or electronic assembly 40 from each other. The top side 11 of the cooling device 10 and the contact surface 41 of the electrical and/or electronic assembly 40 are each flat. The top side 11 of the cooling device 10 and the contact surface 41 of the electrical and/or electronic assembly 40 are arranged plane-parallel to each other.

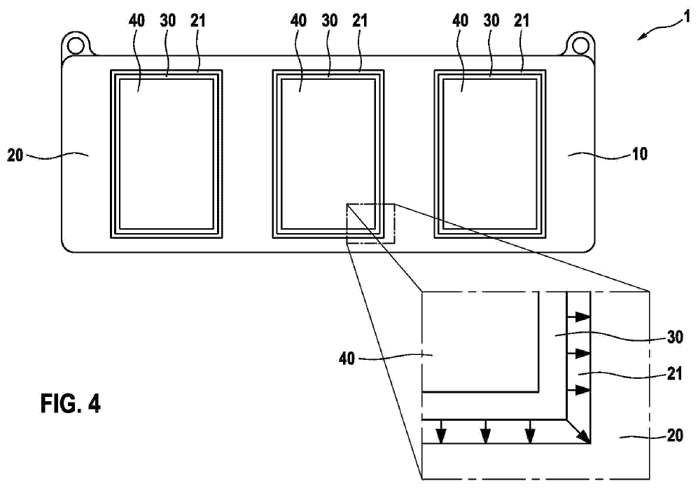

A coating 20 is applied to the top side 11 of the cooling device 10. The coating 20 is formed from nickel. For example, the coating 20 is chemically applied to the top side 11 of the cooling device 10. The coating 20 extends flat on the top side 11 of the cooling device 10. The coating 20 extends in a plane parallel to the contact surface 41 of the electrical and/or electronic assembly 40. At least one recess 21 is configured in the coating 20, within which the top side 11 of the cooling device 10 is not coated. The top surface 11 of the cooling device 11 is only partially coated with the coating 20. In the recess 21 or the recesses 21 of the coating 20, the top side 11 of the cooling device 10 is not coated with the coating 20. In the recess 21, the top side 11 of the cooling device 10 is exposed. The material of the cooling device 1, in particular copper, is thus exposed in the recess 21. The coating 20 with the recess 21 may occur, for example, by masking the top side 11 of the cooling device 10 during application of the coating 20. The masking of the corresponding arcas during the coating process can occur, for example, by clamping on a full-surface mask, clamping on an edge-limiting mask, or masking off the recess 21. The contact surface 41 of the electrical and/or electronic assembly 40 is in contact with the top side 11 of the cooling device 10 in the recess 21. The contact surface 41 of the electrical and/or electronic assembly 40 is attached in the recess 21 on the top side 11 of the cooling device 10. The intermediate layer 30 is arranged entirely in the recess 21 of the coating 20. The intermediate layer 30 is circumferentially surrounded by the coating 20 on the top side 11 of the cooling device 10. FIG. 4 shows how the intermediate layer 30 formed from solder can melt on the exposed copper surface in the recess 21 of the coating 20 and can blur up to the nickel coating 20. Thus, solder flow can be controlled over the shape and size of the recess 21 in the coating 20 and a solder stop function can be achieved. Furthermore, the final positioning of the electrical and/or electronic assembly 40 during the soft soldering process is determined simultaneously by the shape and size of the recess 21 in the coating 20, as during the wetting process of the soft solder of the intermediate layer 30 on the contact surface 41 and on the top side 11 of the cooling device 10 in the recess 21, the wetting forces pull the contact surface 41 of the electrical and/or electronic assembly 40 to the central position of the recess 21. The shape of the recess 21 in the coating 20 corresponds to the shape and size of the exposed uncoated top side 11 of the cooling device, in particular the exposed copper surface.

Of course, further exemplary embodiments and mixed forms of the illustrated exemplary embodiment are also possible.

1. An electrical and/or electronic device (1) comprising:
at least one cooling device (10) having a top side (11),
an electrical and/or electronic assembly (40) arranged on the top (11) of the cooling device (10) having a contact surface (41), wherein the contact surface (41) faces the top side (11) of the cooling device (10) and is attached to the top side (11) of the cooling device (10) by means of an intermediate layer (30) arranged between the cooling device (10) and the contact surface (41) of the electrical and/or electronic assembly (40),
wherein on the top side (11) of the cooling device (10), a laminarly extending coating (20) is arranged on the top side (11) of the cooling device (10), wherein the coating (20) on the top side (11) of the cooling device (10) comprises at least one recess (21), in which the top side (11) of the cooling device (10) is not coated, wherein the contact surface (41) of the electrical and/or electronic assembly (40) in the recess (21) is in contact with the cooling device (10) and attached to the cooling device (10).

2. The electrical and/or electronic device according to claim 1, wherein the contact surface (41) of the electrical and/or electronic assembly (40) in the recess (21) of the coating (20) is soldered to the top side (11) of the cooling device (10), wherein the intermediate layer (30) is configured as a solder layer.

3. The electrical and/or electronic device according to claim 1, wherein the cooling device (10) is formed from copper.

4. The electrical and/or electronic device according to claim 1, wherein the coating (20) is formed from nickel.

5. The electrical and/or electronic device according to claim 1, wherein the recess (21) has a larger surface extent than the contact surface (41).

6. The electrical and/or electronic device according to claim 1, wherein the contact surface (41) is arranged entirely within the recess (21) of the coating (20) on the top side (11) of the cooling device (10).

7. The electrical and/or electronic device according to claim 1, wherein the intermediate layer (30) is arranged entirely within the recess (21) of the coating (20) on the top side (11) of the cooling device (10).

8. A method for manufacturing an electrical and/or electronic assembly, wherein the method comprises the following steps:
providing a cooling device (10) having a top side (11)
coating the top side (11) of the cooling device (10) with a coating (20), wherein the coating (20) is carried out while leaving a recess (21) on the top side (11) of the cooling device (10), wherein the top side (11) of the cooling device (10) is not coated in the recess (21),
providing an electrical and/or electronic assembly (40) having a contact surface (41),
arranging and attaching the contact surface (41) of the electrical and/or electronic assembly (40) in the recess (21) on the top side (11) of the cooling device (10) by means of an intermediate layer (30).

9. A method for manufacturing an electrical and/or electronic assembly according to claim 8, wherein the top side (11) of the cooling device (10) is masked prior to coating.

10. The method for manufacturing an electrical and/or electronic assembly according to claim 9, wherein masking of the top side (11) of the cooling device (10) occurs by clamping on a full-surface mask and/or by clamping on an edge-limiting mask and/or by masking.
